(19) United States
(12) Patent Application Publication
(10) Pub. No.: US 2022/0178026 A1
(43) Pub. Date: Jun. 9, 2022

(54) CARBON CVD DEPOSITION METHODS TO MITIGATE STRESS INDUCED DEFECTS

(71) Applicant: Applied Materials, Inc., Santa Clara, CA (US)

(72) Inventors: Vinayak Vishwanath HASSAN, San Francisco, CA (US); Anup Kumar SINGH, Santa Clara, CA (US); Bhaskar KUMAR, Santa Clara, CA (US)

(21) Appl. No.: 17/110,774

(22) Filed: Dec. 3, 2020

(51) Int. Cl. C23C 16/455; C23C 16/26; C23C 16/505; H01L 21/02

(52) U.S. Cl. CPC C23C 16/45553; C23C 16/26; H01L 21/02617; H01L 21/02444; C23C 16/505

(57) ABSTRACT

A method includes flowing a carbon-containing precursor and a carrier gas into a processing volume having a substrate positioned therein, generating a plasma in the processing volume by applying a first RF bias to a substrate support to deposit a first portion of carbon film onto the substrate, and terminating flow of the carbon-containing precursor while maintaining flow of the carrier gas to maintain the plasma within the processing volume. The method also includes flowing a nitrogen-containing gas into the processing volume and ionizing the nitrogen-containing gas in the presence of the plasma, exposing the substrate having the carbon film thereon to the ionized nitrogen-containing gas for a time period less than three seconds, and terminating flow of the nitrogen-containing gas while maintaining the plasma and reintroducing the carbon-containing precursor into the processing volume in the presence of the plasma to deposit a second portion of the carbon film.

### BACKGROUND

### Field

Embodiments of the present disclosure generally relate to apparatus and methods utilized in the manufacture of semiconductor devices. More particularly, embodiments of the present disclosure relate to methods of depositing carbon-containing films, such as carbon hardmasks.

### Description of the Related Art

Integrated circuits have evolved into complex devices that can include millions of transistors, capacitors and resistors on a single chip. The evolution of chip designs continually involves faster circuitry and greater circuit density. The demands for faster circuits with greater circuit densities impose corresponding demands on the materials used to fabricate such integrated circuits. In particular, as the dimensions of integrated circuit components are reduced to the sub-micron scale, there is a trend to use low resistivity conductive materials as well as low dielectric constant insulating materials to obtain suitable electrical performance from such components.

The demands for greater integrated circuit densities also impose demands on the process sequences used in the manufacture of integrated circuit components. For example, in process depositing a high modulus, high density amorphous carbon films on a substrate with a high power radio frequency bias on the substrate support. As the thickness of these films increase, the defects due to intrinsic stress build up increase exponentially as well. Thus, what is needed in the art are improved methods for fabricating semiconductor devices.

### SUMMARY

The present disclosure generally relates to a method of processing a substrate. In one embodiment, the method includes flowing a carbon-containing precursor and a carrier gas into a processing volume having a substrate positioned therein, generating a plasma in the processing volume by applying a first RF bias to a substrate support to deposit a first portion of carbon film onto the substrate, and terminating flow of the carbon-containing precursor while maintaining flow of the carrier gas to maintain the plasma within the processing volume. The method also includes flowing a nitrogen-containing gas into the processing volume and ionizing the nitrogen-containing gas in the presence of the plasma, exposing the substrate having the carbon film thereon to the ionized nitrogen-containing gas for a time period less than three seconds, and terminating flow of the nitrogen-containing gas while maintaining the plasma and reintroducing the carbon-containing precursor into the processing volume in the presence of the plasma to deposit a second portion of the carbon film.

In another embodiment, a method comprises flowing a carbon-containing precursor and a carrier gas into a processing volume having a substrate positioned therein and generating a plasma in the processing volume by applying a first RF bias to a substrate support to deposit a first portion of carbon film onto the substrate. The method also includes terminating the flow of the carbon-containing precursor and the flow of the carrier gas, flowing ammonia into the processing volume and contacting the carbon film with the ammonia, terminating the flow of the ammonia, and reintroducing the carbon-containing precursor and the carrier gas into the processing volume to deposit a second portion of the carbon film.

In another embodiment, a method comprises flowing a carbon-containing precursor gas and a first carrier gas into a processing volume having a substrate positioned therein, wherein a ratio of the carbon-containing precursor gas to the first carrier gas is about 2:1 to about 1:2, and generating a plasma in the processing volume by applying a first RF bias to a substrate support to deposit a first portion of a carbon film onto the substrate, wherein the first portion of the carbon film has a thickness with a range of about 100 Å to about 500 Å. The method further comprises flowing the carbon-containing precursor gas and a second carrier gas into a processing volume to deposit a second portion of carbon film onto the substrate, wherein the ratio of the carbon-containing precursor gas to the second carrier gas is about 1:5 to about 1:10, and wherein the second portion of the carbon film is has a thickness with a range of about 5 Å to about 30 Å.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic side cross sectional view of a processing chamber, according to one embodiment of the disclosure.

FIG. 2A is a flowchart illustrating a method of deposition according to one embodiment of the disclosure.

FIG. 2B is a flowchart illustrating a method of deposition according to another embodiment of the disclosure.

FIG. 3 is a flowchart illustrating a method of deposition according to another embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to a substrate processing chamber utilized in substrate processing, and methods of depositing carbon-containing films, such as carbon hardmasks. Examples of processing chambers and/or systems that may be adapted to benefit from exemplary aspects of the disclosure include the PIONEER™ PECVD system commercially available from Applied Materials, Inc., located in Santa Clara, Calif. It is contemplated that other processing chambers and/or processing platforms, including those from other manufacturers, may be adapted to benefit from aspects of the disclosure.

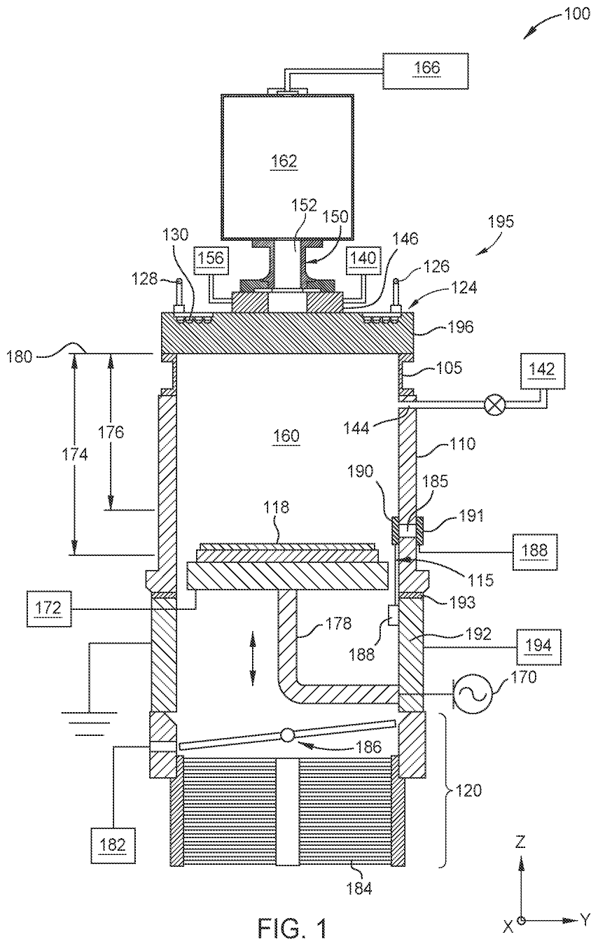

FIG. 1 is a schematic side cross sectional view of an illustrative processing chamber 100 suitable for conducting a deposition process. In one embodiment, the processing chamber 100 is configured to deposit advanced patterning films onto a substrate, such as hardmask films, for example amorphous carbon hardmask films. The processing chamber 100 includes a lid 195, a spacer 110 disposed on a chamber body 192, a substrate support 115, and a variable pressure system 120. A processing volume 160 exists inside the spacer 110 between the lid 195 and the substrate support 115.

The lid 195 is coupled to a first process gas source 140. The first process gas source 140 contains a process gas, such as precursor gas for forming films on a substrate 118 supported on the substrate support 115. As an example, the precursor gas includes one or more of a carbon-containing gas such as acetylene (C₂H₂), a carrier gas, a nitrogen-containing gas, a hydrogen-gas, and/or helium among other gases.

A second process gas source 142 is fluidly coupled to the processing volume 160 via an inlet 144 disposed through the spacer 110. The second process gas source 142 contains a process gas, such as precursor gas, such as those specified above with respect to the first process gas source 140. In one example, the first process gas source 140 and the second process gas source 142 may be gas boxes, which each store and control the flow of multiple different gases to the processing volume 160.

In some embodiments, which may be combined with other embodiments, a total flow rate of precursor gas into the processing volume 160 is about 100 sccm to about 2 slm. A flow rate of precursor gas into the processing volume 160 from the second processing gas source 142 modulates a flow rate of precursor gas into the processing volume 160 from the first processing gas source 140 such that the combined precursor gas is uniformly distributed in the processing volume 160. In one example, a plurality of inlets 144 are distributed circumferentially about the spacer 110. In such an example, gas flow to each of the inlets 144 are separately controlled to further facilitate the uniform distribution of precursor gas within the processing volume 160.

The lid 195 includes a gas distributor 196, such as a dome, nozzle, or showerhead. The gas distributor 196 is coupled to the spacer 110 via a riser 105, but it is contemplated that the riser 105 may be omitted and the gas distributor 196 may be directly coupled to the spacer 110. In some embodiments, which may be combined with other embodiments, the riser 105 is integrated with the gas distributor 196. The lid 195 includes a heat exchanger 124. The heat exchanger 124 is attached to the gas distributor 196 or integrated with the gas distributor 196. The heat exchanger 124 includes an inlet 126 and an outlet 128. In embodiments in which the heat exchanger 124 is integrated with the gas distributor 196, heat exchange fluids flow from the inlet 126, through channels 130 formed in the gas distributor 196, and out of the outlet 128.

The gas distributor 196 is coupled to or integrated with a manifold 146. The gas distributor 196 is coupled to a remote plasma source 162 by a conduit 150, such as a mixing ampoule, having an axial throughbore 152 to facilitate flow of plasma through the conduit 150. Although the conduit 150 is illustrated as coupled to the manifold 146, it is contemplated that the manifold 146 may be integrated with the conduit 150 such that the conduit 150 is directly coupled to the gas distributor 196. The manifold 146 is coupled to the first process gas source 140 and a purge gas source 156. Both of the first process gas source 140 and the purge gas source 156 may be coupled to the manifold 146 by valves (not shown).

Although the lid 195 may be coupled to a remote plasma source 162, in some embodiments, the remote plasma source 162 is omitted. When present, the remote plasma source 162 is coupled to a cleaning gas source 166 via a feed line for providing cleaning gas to the processing volume 160. When the remote plasma source 162 is absent, the cleaning gas source 166 is directly coupled to the conduit 150. When the remote plasma source 162 is absent, the cleaning gas source 166 is indirectly coupled to the conduit 150. Cleaning gas is provided through the conduit 150. Additionally, or alternatively, in some embodiments, cleaning gas is provided through a channel that also conveys precursor gas into the processing volume 160. As an example, the cleaning gas may include an oxygen-containing gas, such as molecular oxygen (O₂) and/or ozone (O₃). As an example, the cleaning gas may include a fluorine-containing gas, such as NF₃. As an example, the cleaning gas may include one or more other gases. As an example, the cleaning gas may include a combination of gases.

In addition to, or as an alternative to, the remote plasma source 162, the lid 195 is coupled to a first, or upper, radio frequency (RF) power source 168. The first RF power source 168 facilitates maintenance or generation of plasma, such as a plasma generated from a cleaning gas. In embodiments in which the remote plasma source 162 is omitted, the cleaning gas may be ionized into a plasma in situ via the first RF power source 168. The substrate support 115 is coupled to a second, or lower, RF power source 170. The first RF power source 168 may be a high frequency RF power source (for example, about 13.56 MHz to about 120 MHz) and the second RF power source 170 may be a low frequency RF power source (for example, about 2 MHz to about 13.56 MHz). It is to be noted that other frequencies are also contemplated. In some implementations, the second RF power source 170 is a mixed frequency RF power source, providing both high frequency and low frequency power. Utilization of a dual frequency RF power source, particularly for the second RF power source 170, improves film deposition. In one example, a first frequency of about 2 MHz to about 13.56 MHz improves implantation of species into the deposited film, while a second frequency of about 13.56 MHz to about 120 MHz increases ionization and deposition rate of the film.

One or both of the first RF power source 168 and the second RF power source 170 may be utilized in creating or maintaining a plasma in the processing volume 160. For example, the second RF power source 170 may be utilized during a deposition process, and the first RF power source 168 may be utilized during a cleaning process (alone or in conjunction with the remote plasma source 162). In some deposition processes, the first RF power source 168 is used in conjunction with the second RF power source 170. During a deposition process, one or both of the first RF power source 168 and the second RF power source 170 provide a power of about 100 Watts (W) to about 20,000 W to the processing volume 160 to facilitation ionization of a precursor gas. In one embodiment, which can be combined with other embodiments described herein, at least one of the first RF power source 168 and the second RF power source 170 are pulsed. In another embodiment, which can be combined with other embodiments described herein, the precursor gas includes helium and C₂H₂. In one embodiment, which can be combined with other embodiments described herein, C₂H₂ is provided at a flow rate of about 10 sccm to about 1,000 sccm and helium is provided at a flow rate of about 50 sccm to about 10,000 sccm.

The substrate support 115 is coupled to an actuator 172 (e.g., a lift actuator) that provides movement thereof in the Z direction. The substrate support 115 is also coupled to a facilities cable 178 that is flexible which allows vertical movement of the substrate support 115 while maintaining communication with the second RF power source 170 as well as other power and/or fluid connections. The spacer 110 is disposed on the chamber body 192. A height of the spacer 110 allows movement of the substrate support 115 vertically within the processing volume 160. The height of the spacer 110 may be from about 0.5 inches to about 20 inches. In one example, the substrate support 115 is movable from a first distance 174 to a second distance 176 relative to the lid 195 (for example, relative to a datum 180 of the gas distributor 196). In one embodiment, the second distance 176 is about two-thirds of the first distance 174. For example, the difference between the first distance 174 and the second distance may be about 5 inches to about 6 inches. Thus, from the position shown in FIG. 1, the substrate support 115 is movable by about 5 inches to about 6 inches relative to a datum 180 of the gas distributor 196. In another example, the substrate support 115 is fixed at one of the first distance 174 and the second distance 176.

In contrast to conventional plasma enhanced chemical vapor deposition (PECVD) processes, the spacer 110 greatly increases the distance between (and thus the volume between) the substrate support 115 and the lid 195. The increased distance between the substrate support 115 and the lid 195 reduces collisions of ionized species in the process volume 160, resulting in deposition of film with less intrinsic stress, such as less than 300 megapascal (MPa), such as a stress of 250 MPa. Films deposited with less stress facilitate improved planarity (e.g., less bowing) of substrates upon which the film is formed. Reduced bowing of substrates results in improved precision of downstream patterning operations.

The variable pressure system 120 includes a first pump 182 and a second pump 184. The first pump 182 is a roughing pump that may be utilized during a cleaning process and/or substrate transfer process. A roughing pump is generally configured for moving higher volumetric flow rates and/or operating a relatively higher (though still sub-atmospheric) pressure. In one example, the first pump 182 maintains a pressure within the processing chamber 100 less than 50 mTorr during a cleaning process. In another example, the first pump 182 maintains a pressure within the processing chamber 100 of about 0.5 mTorr to about 10 Torr. Utilization of a roughing pump during cleaning operations facilitates relatively higher pressures and/or volumetric flow of cleaning gas (as compared to a deposition operation). The relatively higher pressure and/or volumetric flow during the cleaning operation improves cleaning of chamber surfaces.

The second pump 184 is a turbo pump or a cryogenic pump. The second pump 184 is utilized during a deposition process. The second pump 184 is generally configured to operate a relatively lower volumetric flow rate and/or pressure. For example, the second pump 184 is configured to maintain the processing volume 160 of the process chamber at a pressure of less than about 50 mTorr. In another example, the second pump 184 maintains a pressure within the processing chamber of about 0.5 mTorr to about 10 Torr. The reduced pressure of the processing volume 160 maintained during deposition facilitates deposition of a film having reduced stress and/or increased sp²-sp³ conversion, when depositing carbon-based hardmasks. Thus, process chamber 100 is configured to utilize both relatively lower pressure to improve deposition and relatively higher pressure to improve cleaning.

In some embodiments, which can be combined with other embodiments described herein, both of the first pump 182 and the second pump 184 are utilized during a deposition process to maintain the processing volume 160 of the process chamber at a pressure of less than about 50 mTorr. In other embodiments, the first pump 182 and the second pump 184 maintain the processing volume 160 at a pressure of about 0.5 mTorr to about 10 Torr. A valve 186 is utilized to control a conductance path to one or both of the first pump 182 and the second pump 184. The valve 186 also provides for symmetrical pumping from the processing volume 160.

The processing chamber 100 also includes a substrate transfer port 185. The substrate transfer port 185 is selectively sealed by one or both of an interior door 190 and an exterior door 191. Each of the doors 190 and 191 are coupled to actuators 188 (i.e., a door actuator). The doors 190 and 191 facilitate vacuum sealing of the processing volume 160. The doors 190 and 191 also provide symmetrical RF application and/or plasma symmetry within the processing volume 160. In one example, at least the interior door 190 is formed of a material that facilitates conductance of RF power, such as stainless steel, aluminum, or alloys thereof. Seals 193, such as O-rings, disposed at the interface of the spacer 110 and the chamber body 192 may further seal the processing volume 160. A controller 194 is configured to control aspects of the processing chamber 100 during processing. The control incudes hardware and software for executing one or more methods described herein.

In operation, the processing chamber 100 is utilized to deposit amorphous carbon films onto substrates. In conventional processes, defects form producing low quality films. As the thickness of these films increase, the occurrence of defects increases exponentially. However, using methods described herein, such as a plasma-based intermittent treatment to relieve stress or novel process chemistries, defects are reduced.

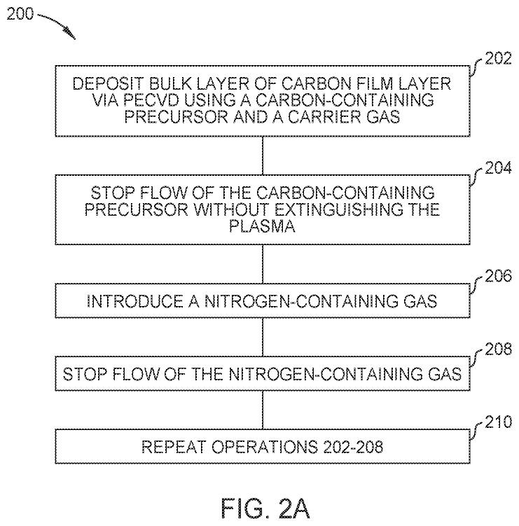

FIG. 2A depicts a method 200 for a plasma-based treatment for mitigating intrinsic stress build up in films, such as carbon films. At operation 202, a bulk layer of carbon is deposited via PECVD on a substrate 118 supported by substrate support 115 (shown in FIG. 1). In operation 202, a carbon-containing precursor gas, such as acetylene (C₂H₂), and a carrier gas, such as helium (He) are introduced to the processing volume of a process chamber and ionized to form a capacitively coupled plasma. The C₂H₂ and He facilitate deposition of a carbon film on the substrate. Operation 202 may occur for a time period of about 30 seconds to about 120 seconds, such as about 45 seconds to about 75 seconds. The carbon film is deposited on the substrate to a first thickness that ranges from about 1 Å to about 1000 Å, such as about 100 Å to about 500 Å. The process chamber interior volume is maintained at a pressure that ranges from about 3 mTorr to about 20 mTorr during carbon film deposition. The flow rate of the carbon-containing gas ranges from about 30 sccm to about 1000 sccm. The temperature of the substrate ranges from about 10° C. to about 20° C. during the carbon film deposition. As a consequence of deposition on the substrate, carbon is also deposited on internal surfaces within the process chamber housing the substrate. Due to the relatively large process volume of the process chamber, which is created in response to the increased spacing between the substrate support and the gas distributor (for example, about 4 inches to about 18 inches, such as about 6 inches to about 16 inches, such as about 7 inches to about 14 inches, such as about 11 inches to about 14 inches), the film deposited on the substrate includes a great amount of spa carbon, with lower intrinsic stress, than film deposited on surfaces of the chamber. While operation 202 describes C₂H₂ gas as the carbon-containing precursor, other carbon-containing precursor gases are also contemplated.

At operation 204, the flow of the carbon-containing precursor (e.g., acetylene) is halted without extinguishing the plasma (e.g., flow of the carrier gas continues). All other processing conditions may remain unchanged. The continued flow the carrier gas and the continued application of RF power maintain a plasma (of the carrier gas) within the process chamber.

At operation 206, a nitrogen-containing gas is introduced to the processing volume, generating a nitrogen-containing plasma. It is noted that the substrate remains in the processing volume while the nitrogen-containing plasma is generated, thereby improving processing throughput. The nitrogen-containing gas includes one or more of ammonia (NH₃), diatomic nitrogen (N₂), or nitrogen trifluoride (NF₃). When utilizing NF₃, the relatively small exposure time of NF₃ to the substrate (such as about 5 seconds or less), and/or other process conditions described below, minimizes etching of the carbon film by the fluorine. The nitrogen-containing plasma is maintained for a period of time less than about 5 seconds or less than about 3 seconds, such as about 0.5 seconds to about 3 seconds, such as 1 second, in the absence of the carbon-containing precursor. The nitrogen-containing plasma is maintained for about 1% to about 2% of the total deposition time (e.g., the process time during operation 206 is about 1% to about 2% of the process time for the top of operation 202 and 206). The internal volume of the process chamber is maintained at a pressure of about 3 mTorr to about 20 mTorr while the nitrogen-containing plasma is maintained. The flow rate of the nitrogen-containing gas is about 30 sccm to about 1000 sccm. The temperature of the substrate ranges from about 10° C. to about 20° C. The nitrogen-containing plasma is introduced after a deposition of carbon-film having a thickness ranging from about 1 Å to about 1000 Å, such as about 100 Å to about 500 Å.

Minimal to no nitrogen is incorporated in the resulting carbon film on the substrate due to the relatively small exposure time of the substrate to the nitrogen-containing plasma. However, exposure of carbon films to nitrogen results in a decrease in the intrinsic stress of the deposited carbon films. For example, exposure of the carbon film on the substrate to nitrogen reduces the intrinsic stress of the carbon film on the substrate, which reduces the occurrence of bowing and increases downstream processing accuracy. Likewise, exposure of carbon film on the internal surfaces of process chamber to nitrogen reduces the intrinsic stress of the carbon film on internal surfaces of the process chamber. The carbon film deposited on the internal surfaces of the process chamber is of lower quality (e.g., less spa carbon) than the carbon film deposited on the substrate. The exposure to nitrogen of operation 206 has a greater effect of reducing the intrinsic stress of the lower quality carbon film on the chamber components than the higher quality carbon film deposited on the substrate. The reduced stress reduces the occurrence of cracking/flaking of the carbon film on interior chamber surfaces (which would otherwise increase exponentially as film thickness increases in the absence of the nitrogen-containing plasma exposure), thereby reducing contamination on the substrate. Moreover, the minimal incorporation of nitrogen into the carbon film on the substrate does not alter the properties of the carbon film relative to a similar process which does not include the nitrogen exposure process described herein.

At operation 208, the flow of the nitrogen-containing gas is halted without extinguishing the plasma. Maintaining the plasma ignition through the process facilitates minimal nitrogen-containing plasma exposure as well as rapid transitioning between the nitrogen-containing gas and the carbon-containing precursor. At operation 210, operations 202-208 are repeated until a desired film thickness is reached. The resulting film thickness formed on the substrate, such as substrate 118, may be between about 5000 Å to about 3.5 microns, such as 1 micron and about 3 microns. The inclusion of intermittent treatments, such as that of operation 206, reduces the occurrence of contamination while extending the time (or deposition processes) between cleanings, improving throughput, for depositing carbon hardmask films of 1 micron or greater.

FIG. 2B is a flowchart illustrating a method 250 of deposition according to another embodiment of the disclosure. Method 250 begins at operation 212. At operation 212, a bulk layer of carbon is deposited via PECVD, forming a carbon film on a substrate 118 supported by substrate support 115 (See FIG. 1). As a result of the deposition process, carbon film is also deposited on internal surfaces of the process chamber. In operation 212, a carbon-containing precursor gas, such as acetylene (C₂H₂), and a carrier gas, such as helium (He), are introduced to the processing volume of a process chamber and ionized to form a capacitively coupled plasma. The C₂H₂ and He facilitate deposition of the carbon film on the substrate. The carbon film is deposited on the substrate to a first thickness with a range of about 1 Å to about 1000 Å, such as about 100 Å to about 500 Å. Operation 202 may occur for a time period of about 30 seconds to about 120 seconds, such as about 45 seconds to about 75 seconds. While operation 212 describes C₂H₂ gas as the carbon-containing precursor, other carbon-containing precursor gases are also contemplated.

At operation 214, the flow of the carbon-containing precursor is halted and RF power application is stopped, extinguishing the plasma. Flow of the carrier gas is continued. All other processing conditions may remain unchanged, facilitating rapid transition between processes, leading to greater throughput.

At operation 216, NH₃ gas is introduced into the processing volume 160, optionally in conjunction with a carrier gas such as helium. It is noted that the substrate remains in the processing volume while the NH₃ gas is introduced into the processing volume, thereby improving processing throughput. Utilizing the lone pair of electrons of NH₃, a hydrogen-carbonated surface on the film is created. Minimal to no nitrogen is incorporated into the resulting carbon film. The NH₃ acts as a catalyst, encouraging bonding for subsequent carbon deposition. The NH₃ gas is introduced for a period of time less than about 5 seconds or less than about 3 seconds, such as about 0.5 seconds to about 3 seconds, such as about 1 second, in the absence of the carbon-containing precursor plasma. The NH₃ gas is maintained for about 1% to about 2% of the total deposition time (e.g., operation 216 occurs for about 1% to about 2% of the total combined time of operation 212 and 216). The NH₃ gas is introduced after a deposition of carbon-film ranging from about 1 Å to about 1000 Å, such as about 100 Å to about 500 Å. The brief exposure time of the NH₃ gas sufficient to create an ammonia-terminated surface, which acts as a catalyst to improve carbon bonding, thereby reducing flaking of carbon film from interior surfaces of the process chamber. The carbon film deposited on the internal surfaces of the process chamber is of lower quality (e.g., reduced spa content) than the carbon film deposited on the substrate. The exposure to NH₃ of operation 216 has a greater effect of reducing the intrinsic stress of the lower quality carbon film on the chamber components than the higher quality carbon film deposited on the substrate. The reduced stress reduces the occurrence of cracking/flaking of the carbon film on chamber surfaces (which would otherwise increase exponentially as film thickness increases in the absence of the nitrogen-containing plasma exposure), thereby reducing contamination on the substrate. The process chamber internal volume is introduced at a pressure of about 3 mTorr to about 20 mTorr during operation 216. The flow rate of the NH₃ gas ranges from about 30 sccm to about 1000 sccm. The temperature of the substrate ranges from about 10° C. to about 20° C. during operation 216. In one example, the NH₃ remains in a gaseous state during operation 216.

At operation 218, the flow of NH₃ gas is halted, while all other processing conditions remain unchanged. At operation 220, operations 212-218 are repeated until a desired film thickness is reached. The resulting film formed on the substrate, such as substrate 118, may be between about 5000 Å to about 3.5 microns thick, such as about 1 micron and about 3 microns thick.

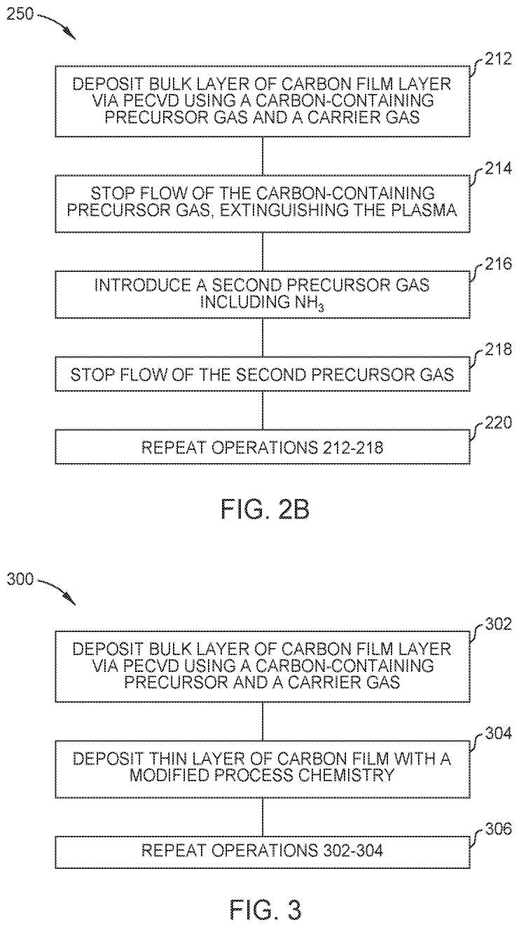

FIG. 3 is a flowchart illustrating a method 300 of depositing a carbon film, such as a carbon hardmask, according to another embodiment of the disclosure. Method 300 includes the deposition of an ultra-thin film on a substrate and on interior surfaces of the process chamber to mitigate intrinsic stress defects, and may be used in conjunction with either method 200 or method 250 described above.

Method 300 begins at operation 302. At operation 302, a bulk layer of carbon is deposited via PECVD, forming a carbon film on a substrate 118 supported by substrate support 115 (See FIG. 1). As a result of the deposition process, carbon film is also deposited on internal surfaces of the process chamber. In operation 302, a carbon-containing precursor gas, such as acetylene (C₂H₂), and a carrier gas, such as helium or argon, are introduced to the processing volume of a process chamber and ionized to form a capacitively coupled plasma. The carbon-containing precursor and the carrier gas facilitate deposition of the carbon film on the substrate. The carbon film is deposited to a first thickness with a range of about 1 Å to about 1000 Å, such as about 100 Å to about 500 Å. Operation 302 may occur for a time period of about 30 seconds to about 120 seconds, such as about 45 seconds to about 75 seconds. While operation 302 describes C₂H₂ gas as the carbon-containing precursor, other carbon-containing precursor gases are also contemplated. The ratio of the carbon-containing precursor (e.g., C₂H₂) to carrier gas (e.g., He) flow rate is about 1:1 to about 1:10, such as about 1:2 during operation 302. The carbon-containing precursor gas is provided to the processing chamber at a flow rate ranging from about 30 sccm to about 1000 sccm. The temperature of the substrate is maintained during the deposition within a range of about 10° C. to about 20° C. The pressure of the processing volume 160 is maintained at about 3 mTorr to about 20 mTorr.

At operation 304, the process chemistry of the carbon-containing precursor gas and the carrier gas is changed, for example, by switching carrier gases, introducing an additional carrier gas, or introducing a nitrogen-containing dopant. Other process chemistry changes may include adjusting the ratio of carrier gas to carbon-containing gas, or adjusting one or more of pressure, flow rate, RF power, or bias power within the chamber, which may directly or indirectly influence the composition of radicals (E.g., which radical species and/or relative ratios therebetween) within the process volume. In one example, while the ratio of the carbon-containing precursor to the carrier gas is 1:1 at operation 302, the ratio the carbon-containing precursor to carrier gas ratio may be adjusted to within a range of 1:5 to 1:10 at operation 304. By varying the ratio of carbon-containing precursor to the carrier gas (or by varying the process chemistry through other manners described above), the stress and the microstructure of the film can be varied. By adjusting the ratio of the precursor gas to the inert gas, the plasma power, and the pressure, the species in the plasma are resultantly changed, controlling the stress and the microstructure of the carbon film. The thickness of the film deposited at operation 304 may be between about 1 Å to about 50 Å, such as about 5 Å to about 30 Å.

In another embodiment, a nitrogen-doped film is deposited at operation 304. In this embodiment, the nitrogen or nitrogen based compound, such as NH₃, controls the film stress on the chamber body, such as by controlling morphology of the film. The lone pair of electrons of NH₃ functions as a catalyst to break down the carbon-containing precursor, resulting in growth of a film with better cohesion. In this embodiment, a nitrogen-containing gas is introduced at a flow rate of about 20 sccm to about 100 sccm, in addition to the carbon-containing precursor and the carrier gas. The concentration of nitrogen in the deposited film is less than about 5 atomic percent. In this embodiment, the flow rate ratio of carbon-containing gas to carrier gas is 1:1. The thickness of the film deposited at operation 304 may be between about 1 Å to about 50 Å thick, such as about 5 Å to about 30 Å thick. The nitrogen-doped film deposited at operation 304 occurs iteratively, such as after about 100 Å to about 500 Å deposition of the carbon deposited at operation 302, resulting in a layered resultant film.

In yet another embodiment, an argon plasma is utilized to deposit the carbon film at operation 304. The argon plasma may be used instead of helium. Due to the varied electron temperature between argon and helium, the C₂H₂ breaks up differently (e.g., into different radicals and/or into different ratios of radicals), controlling the plasma density and modifying the microstructure of the film deposited at operation 304. Thus, a carbon film may be deposited on a substrate (and correspondingly on internal surfaces of the process chamber) using a single carbon-containing precursor but while alternating carrier gases. While argon and helium are used as examples, it is contemplated that other carrier gases (such as process inert and/or noble gases) may be used in operations 302 and 304. Thus, the characteristics of deposited films can be adjusted simply by using different carrier gas compositions at different times during deposition.

At operation 306, operations 302-304 are repeated until a desired film thickness is reached. The resulting film thickness formed on the substrate, such as substrate 118, is between about 1 micron and about 3 microns thick.

Examples provided herein adjust the intrinsic stress of carbon films, mitigating inadvertent bowing of substrates as well as mitigating flaking of carbon films from chamber components. Treatment processes described herein can be performed while a substrate remains in the processing environment of the chamber, improving throughput, but while maintaining the carbon film, such as a carbon hardmask, on the substrate within process specifications.

While the foregoing is directed to embodiments of the present disclosure, other and further embodiments of the disclosure may be devised without departing from the basic scope thereof, and the scope thereof is determined by the claims that follow.

What is claimed:

1. A method of processing a substrate, comprising:
flowing a carbon-containing precursor and a carrier gas into a processing volume having a substrate positioned therein;
generating a plasma in the processing volume by applying a first RF bias to a substrate support to deposit a first portion of a carbon film onto the substrate,
terminating flow of the carbon-containing precursor while maintaining flow of the carrier gas to maintain the plasma within the processing volume;
flowing a nitrogen-containing gas into the processing volume and ionizing the nitrogen-containing gas in the presence of the plasma;
exposing the substrate having the carbon film thereon to the ionized nitrogen-containing gas for a time period less than three seconds;
terminating flow of the nitrogen-containing gas while maintaining the plasma; and
reintroducing the carbon-containing precursor into the processing volume in the presence of the plasma to deposit a second portion of the carbon film.

2. The method of claim 1, wherein the substrate is maintained at a temperature within a range of about 10° C. to about 20° C.

3. The method of claim 1, wherein the processing volume is maintained at a pressure within a range of about 3 mTorr to about 20 mTorr.

4. The method of claim 1, wherein a flow rate of the carbon-containing precursor is within a range of about 30 sccm to about 1000 sccm.

5. The method of claim 1, wherein the carbon-containing precursor is introduced for about 30 seconds to about 120 seconds

6. The method of claim 1, wherein the carbon film is deposited to a final total thickness of about 1 micron and about 3 microns.

7. The method of claim 1, wherein the carbon-containing precursor is acetylene.

8. A method of processing a substrate, comprising:
flowing a carbon-containing precursor and a carrier gas into a processing volume having a substrate positioned therein;
generating a plasma in the processing volume by applying a first RF bias to a substrate support to deposit a first portion of a carbon film onto the substrate;
terminating the flow of the carbon-containing precursor and the flow of the carrier gas;
flowing ammonia into the processing volume and contacting the carbon film with the ammonia;
terminating the flow of the ammonia; and
reintroducing the carbon-containing precursor and the carrier gas into the processing volume to deposit a second portion of the carbon film.

9. The method of claim 8, wherein the ammonia is flowed into the processing volume for time of less than 3 seconds.

10. The method of claim 8, wherein the ammonia remains in a gaseous state.

11. The method of claim 8, wherein a flow rate of the carbon-containing precursor is within a range of about 30 sccm to about 1000 sccm.

12. The method of claim 8, wherein the carbon-containing precursor is introduced for about 30 seconds to about 120 seconds

13. The method of claim 8, wherein the ammonia is introduced for about 0.5 seconds to about 3 seconds.

14. The method of claim 8, wherein the carbon film is deposited to a final total thickness of about 1 micron and about 3 microns.

15. The method of claim 8, wherein the carbon-containing precursor is acetylene.

16. A method of processing a substrate, comprising:
flowing a carbon-containing precursor gas and a first carrier gas into a processing volume having a substrate positioned therein, wherein a ratio of the carbon-containing precursor gas to the first carrier gas is about 2:1 to about 1:2;
generating a plasma in the processing volume by applying a first RF bias to a substrate support to deposit a first portion of a carbon film onto the substrate, wherein the first portion of the carbon film has a thickness with a range of about 100 Å to about 500 Å; and
flowing the carbon-containing precursor gas and a second carrier gas into a processing volume to deposit a second portion of carbon film onto the substrate, wherein the ratio of the carbon-containing precursor gas to the second carrier gas is about 1:5 to about 1:10, and wherein the second portion of the carbon film is has a thickness with a range of about 5 Å to about 30 Å.

17. The method of claim 16, wherein the first carrier gas is helium and the second carrier gas is argon.

18. The method of claim 16, wherein the carbon-containing precursor gas is acetylene.

19. The method of claim 16, wherein the first carrier gas is the same as the second carrier gas.

20. The method of claim 16, wherein the carbon film is a hardmask and is deposited to a final total thickness of about 1 micron and about 3 microns.
